(19) United States
(12) Patent Application Publication
(10) Pub. No.: US 2013/0334534 A1
(43) Pub. Date: Dec. 19, 2013

(54) LIQUID CRYSTAL DISPLAY AND METHOD OF MANUFACTURING THE SAME

(71) Applicant: MITSUBISHI ELECTRIC CORPORATION, Tokyo (JP)

(72) Inventors: Tatsuya FUJII, Tokyo (JP); Toru TAKEGUCHI, Kumamoto (JP); Takafumi HASHIGUCHI, Tokyo (JP)

(21) Appl. No.: 13/920,771

(22) Filed: Jun. 18, 2013

(30) Foreign Application Priority Data
Jun. 18, 2012 (JP) 2012-137105

(51) Int. Cl. H01L 27/12

(52) U.S. Cl. CPC H01L 27/1248; H01L 27/1259
USPC 257/59; 257/72; 438/30

(57) ABSTRACT

A liquid crystal display which includes a first substrate having thin film transistors, and a second substrate disposed to face the first substrate, wherein the first substrate includes: a gate electrode, a source electrode, and a drain electrode; a gate wiring; a first insulating film formed on the gate electrode and the gate wiring; a source wiring; a pixel electrode that is formed on the drain electrode to partially overlap the drain electrode; a second insulating film that covers the pixel electrode; a counter electrode; and a side wall that is formed on side portions of the source wiring, the source electrode, and the drain electrode, the third insulating film made of third insulating film; and wherein at least a part of the pixel electrode is formed to directly overlap the drain electrode and the side wall formed on the side portion of the drain electrode.

### CROSS-REFERENCE TO RELATED APPLICATION

This application claims priority from Japanese Patent Application No. 2012-137105 filed on Jun. 18, 2012, the entire subject matter of which is incorporated herein by reference.

### TECHNICAL FIELD

This disclosure relates to a thin film transistor array substrate, a method of manufacturing the thin film transistor array substrate, and a liquid crystal display, and specifically, to a thin film transistor array substrate which is used for a fringe field switching mode liquid crystal display, a method of manufacturing the thin film transistor array substrate, and a liquid crystal display.

### BACKGROUND

Recently, for an improvement of the aperture ratios of pixels or a reduction in cost, a smaller number of masks and structures with a smaller number of inter-layer insulating layers between conductive layers have been developed. Specifically, Fringe Field Switching (hereinafter, referred to as FFS) mode liquid crystal displays for high image quality are a display type of applying a fringe electric field to liquid crystal interposed between substrates facing each other, thereby performing display.

In an FFS mode liquid crystal display, on the TFT substrate side, pixel electrodes and counter electrodes are made of transparent conductive layers with an insulating layer interposed therebetween to be a laminated structure. Therefore, it is possible to obtain an aperture ratio and transmittance higher than those of an In-Plane Switching (IPS) mode. However, since it is difficult to form the pixel electrodes and the counter electrode at the same time, the cost of a process of manufacturing a TFT array substrate increases.

In this regard, there are known manufacturing methods of forming pixel electrodes to overlap directly on the drain electrodes of thin film transistors and forming a counter electrode capable of producing a fringe electric field between the counter electrode and the pixel electrodes through an inter-layer insulating layer. According to these methods, it is possible to make it unnecessary a process of forming contact holes to be a factor that decreases the aperture ratios of the pixel electrodes, without increasing the number of photomasks (JP-A-2010-191410 and U.S. Patent Application Publication No. 2008/0303024 A1).

However, in a case of making an FFS mode liquid crystal display in that configuration, pixel electrodes are formed to overlap on the drain electrodes of thin film transistors. Therefore, depending on the shapes of the side portions of the end portions of the drain electrode patterns which the pixel electrodes will cover, the covering properties of the pixel electrodes may be deteriorated, resulting in disconnection of the pixel electrodes. In this case, if the pixel electrodes are thinned for increasing the transmittance, disconnection of the pixel electrodes becomes more likely to occur, and thus display defects are often generated.

As a measure against disconnection of metal wirings as described above, there are the following two technologies. In a case of covering source/drain electrodes and wirings which are conductive layers simply with an inter-layer insulating layer, disconnection of the wirings may be caused by penetration of a chemical or the like from step portions of the metal wirings. In order to reduce this disconnection, there have been proposed a wiring substrate in which side walls are formed on source/drain electrodes and the like such that the covering properties of an insulating layer and pixel electrodes to be formed thereon are improved and disconnection is suppressed, and a method of manufacturing the wiring substrate, and a display device (JP-A-4-195122).

In a case where there are eave-shaped portions in source/drain electrodes and wirings which are conductive layers, if the source/drain electrodes and the wiring are covered simply with an inter-layer insulating layer, the conductive layers at positions corresponding to the eave-shaped portions may be damaged. In order to suppress this damage, there have been proposed a wiring substrate in which by the side portions of wirings are buried by an application type insulating layer such that it is possible to suppress damage of the conductive layer, a method of manufacturing the wiring substrate, and a display device (JP-A-2007-116029).

In other words, there have been proposed a display device capable of improving the covering properties of wirings and electrodes of an upper layer which is formed on an inter-layer layer or a passivation layer which covers wirings and electrodes of a lower layer, and a display device capable of suppressing damage of wirings and electrodes of an upper layer due to the surface shapes of wirings and electrodes of a lower layer.

### SUMMARY

However, it is difficult to solve disconnection of pixel electrodes occurring in a liquid crystal display having pixel electrodes formed to overlap on the drain electrodes of thin film transistors. Further, since pixel electrodes of that FFS mode are formed inside pixel areas surrounded by source wirings of a layer including the pixel electrodes, the pixel electrodes and the source wirings of the layer including the pixel electrodes may be short-circuited due to residues after etching for forming the pixel electrodes, or pattern abnormality. If this short-circuiting occurs between the source wirings and the pixel electrodes, signals of the source wirings are transmitted to the pixel electrodes without passing through thin film transistors, causing display defects. In this case, the short-circuiting becomes a factor for a reduction in yield.

Also, since it is necessary to suppress adhesion with an ohmic-contact layer of a lower layer and diffusion into the ohmic-contact layer, the source/drain electrodes of thin film transistors are made of alloys or a lamination of them. When an n-type silicon layer which is an ohmic-contact layer is removed by dry etching in order to form the channel areas of so-called back channel type TFTs, a channel etching gas component and the electrode materials of the source/drain electrodes may react together by the alloy composition or the form of the lamination, thereby resulting in conductive reaction products remaining on the channels. If the residues are electrically conductive, a current leak path is formed between the sources and drains of the transistors and adversely affects the leak property during the OFF time of the transistors, resulting in defects of the display properties.

This disclosure provides at least an FFS type liquid crystal display having a TFT array substrate capable of suppressing the leak properties of transistors from being deteriorated while suppressing a reduction in the yield due to disconnection or short-circuiting of electrodes of the TFT array substrate, without changing the layout or materials of wirings and the electrodes, and a method of manufacturing the liquid crystal display.

A liquid crystal display according to this disclosure includes a first substrate having thin film transistors, a second substrate disposed to face the first substrate, and liquid crystal interposed between the first substrate and the second substrate. The first substrate includes: a gate electrode, a source electrode, and a drain electrode that configure the thin film transistor; a gate wiring that is connected to the gate electrode; a first insulating film that is formed on the gate electrode and the gate wiring; a source wiring that is formed to be perpendicular to the gate wiring, and are connected to the source electrode; a pixel electrode that is formed on the drain electrode formed on the first insulating film such that the pixel electrode partially overlap the drain electrode; a second insulating film that covers the pixel electrode; a counter electrode that is formed on the second insulating film and has slits to generate a fringe electric field between the counter electrode and the pixel electrode; and a side wall that is formed on side portions of the source wiring, the source electrode, and the drain electrode, the third insulating film made of third insulating film; and wherein at least a part of the pixel electrode is formed to directly overlap the drain electrode and the side wall formed on the side portion of the drain electrode.

According to this disclosure, in an FFS mode liquid crystal display, it is possible to suppress display defects according to deterioration of a leak property due to metal contaminations between channels, short-circuiting between source wiring and pixel electrodes, and a reduction in yield due to disconnection of the pixel electrodes at the end portions of drain electrodes.

### BRIEF DESCRIPTION OF THE DRAWINGS

The foregoing and additional features and characteristics of this disclosure will become more apparent from the following detailed descriptions considered with the reference to the accompanying drawings, wherein:

FIG. 1 is a front view illustrating the configuration of a TFT array substrate which is used in a liquid crystal display;

FIG. 2 is a plan view illustrating the pixel configuration of a TFT array substrate which is used in a liquid crystal display according to a first embodiment;

FIGS. 3A to 3C are cross-sectional views illustrating the pixel configuration of the TFT array substrate which is used in the liquid crystal display according to the first embodiment;

FIG. 4 is a plan view illustrating the pixel configuration of a TFT array substrate which is used in a liquid crystal display according to a second embodiment; and

FIGS. 5A to 5C are cross-sectional views illustrating the pixel configuration of the TFT array substrate which is used in the liquid crystal display according to the second embodiment.

### DETAILED DESCRIPTION

### First Embodiment

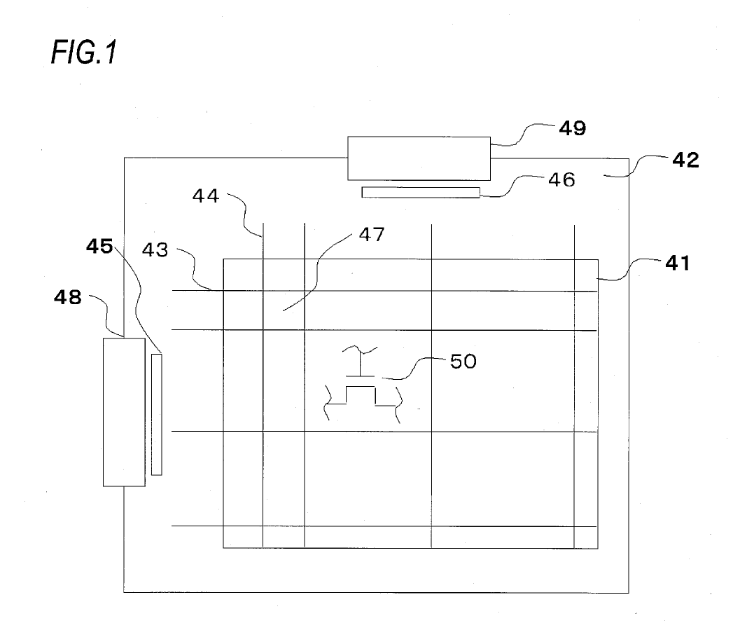

First, a liquid crystal display according to the present embodiment will be described with reference to FIG. 1. FIG. 1 is a front view illustrating the configuration of a Thin Film Transistor (TFT) array substrate which is used in the liquid crystal display according to the present embodiment. The liquid crystal display according to the present embodiment is an FFS mode liquid crystal display having pixel electrodes and counter electrodes formed on a TFT array substrate. The overall configuration of the liquid crystal display will be described below.

The liquid crystal display according to the present embodiment provided with a substrate 10. For example, the substrate 10 is an array substrate such as a TFT array substrate. The substrate 10 includes a display area 41 and a frame area 42 provided to surround the display area 41. In the display area 41, a plurality of gate wirings (scan signal lines) 43 and a plurality of source wirings (display signal lines) 44 are formed. The plurality of gate wirings 43 are provided in parallel. Similarly, the plurality of source wirings 44 are provided in parallel. The gate wirings 43 and the source wirings 44 are formed to intersect with each other. An area surrounded by neighboring gate wirings 43 and source wirings 44 configures a pixel 47. Therefore, pixels 47 are arranged in a matrix, on the substrate 10.

In the frame area 42 of the substrate 10, a scan signal driver circuit 45 and a display signal driver circuit 46 are provided. The gate wirings 43 extend from the display area 41 to the frame area 42, and are connected to the scan signal driver circuit 45 at the end portion of the substrate 10. Similarly, the source wirings 44 also extend from the display area 41 to the frame area 42, and are connected to the display signal driver circuit 46 at the end portion of the substrate 10. An external wiring 48 is connected to the vicinity of the scan signal driver circuit 45. Also, an external wiring 49 is connected to the vicinity of the display signal driver circuit 46. For instance, the external wirings 48 and 49 are wiring substrates such as flexible printed circuits (FPC).

Through the external wirings 48 and 49, various external signals are supplied to the scan signal driver circuit 45 and the display signal driver circuit 46. Based on an external control signal, the scan signal driver circuit 45 suppoverlaps a gate signal (a scan signal) to the gate wirings 43. According to the gate signal, the gate wirings 43 are sequentially selected. The display signal driver circuit 46 suppoverlaps a display signal to the source wirings 44, based on display data or a control signal from the outside. Therefore, it is possible to supply a display voltage according to the display data to each pixel 47.

In each pixel 47, at least one TFT 50 is formed. A TFT 50 is disposed in the vicinity of the intersection of a source wiring 44 and a gate wiring 43. For example, the TFT 50 suppoverlaps a display voltage to a pixel electrode. In other words, according to a gate signal from the gate wiring 43, the TFT 50 being a switching element is turned on. Therefore, the display voltage is applied from the source wirings 44 to a pixel electrode connected to the drain electrode of the TFT 50. Further, the pixel electrode is disposed to face a common electrode (a counter electrode) having slits, with an insulating layer interposed therebetween. Between the pixel electrode and the counter electrode, a fringe electric field according to the display voltage is generated. Also, on a surface of the substrate 10, an alignment film (not shown) is formed. The detailed configuration of the pixels 47 will be described below.

Further, a counter substrate is disposed to face the substrate 10. For example, the counter substrate is a color filter substrate and is disposed on the viewer side. On the counter substrate, color filters, a black matrix (BM), an alignment film, and the like are formed. Between the substrate 10 and the counter substrate, a liquid crystal layer is interposed. In other words, the liquid crystal is introduced between the substrate 10 and the counter substrate. Further, polarizing plates, retardation films, and the like are provided on the outer surfaces of the substrate 10 and the counter substrate. Also, a backlight unit and the like are disposed on the opposite side of the liquid crystal panel to the viewer side.

The liquid crystal is driven according to the fringe electric field between the pixel electrodes and the counter electrode. In other words, the orientation of the liquid crystal interposed between the substrates is changed. Therefore, the polarization state of light passing through the liquid crystal layer is changed. In other words, light linearly polarized through a polarizing plate changes in the polarization state by the liquid crystal layer. Specifically, light from the backlight unit is linearly polarized by the polarizing plate on the array substrate side. The linearly polarized light passes through the liquid crystal layer, thereby changing in the polarization state.

According to the polarization state, an amount of light passing through the polarizing plate on the counter substrate side changes. In other words, among light emitted from the backlight unit and passing through the liquid crystal panel, an amount of light passing through the polarizing plate on the viewer side changes. The orientation of the liquid crystal changes according to the applied display voltage. Therefore, it is possible to change the amount of light to pass through the polarizing plate on the viewer side by controlling the display voltage. In other words, it is possible to display a desired image by changing the display voltage for each pixel.

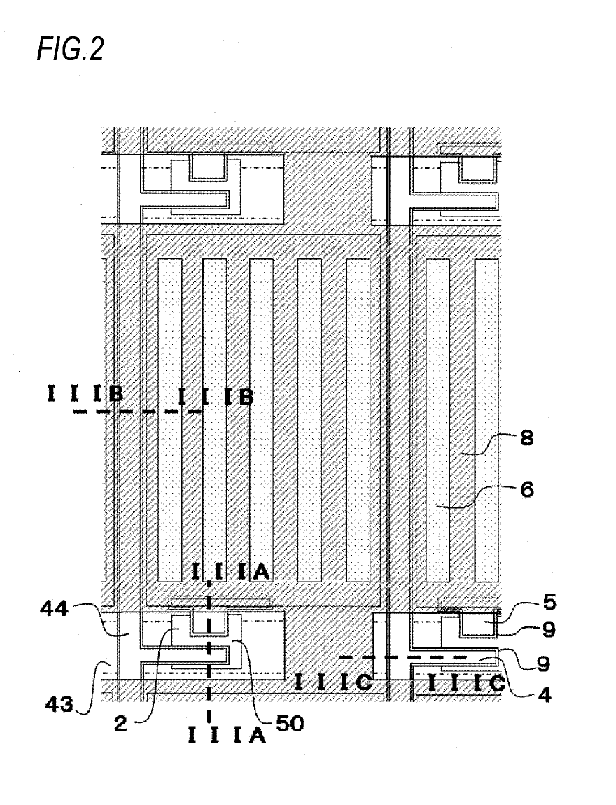

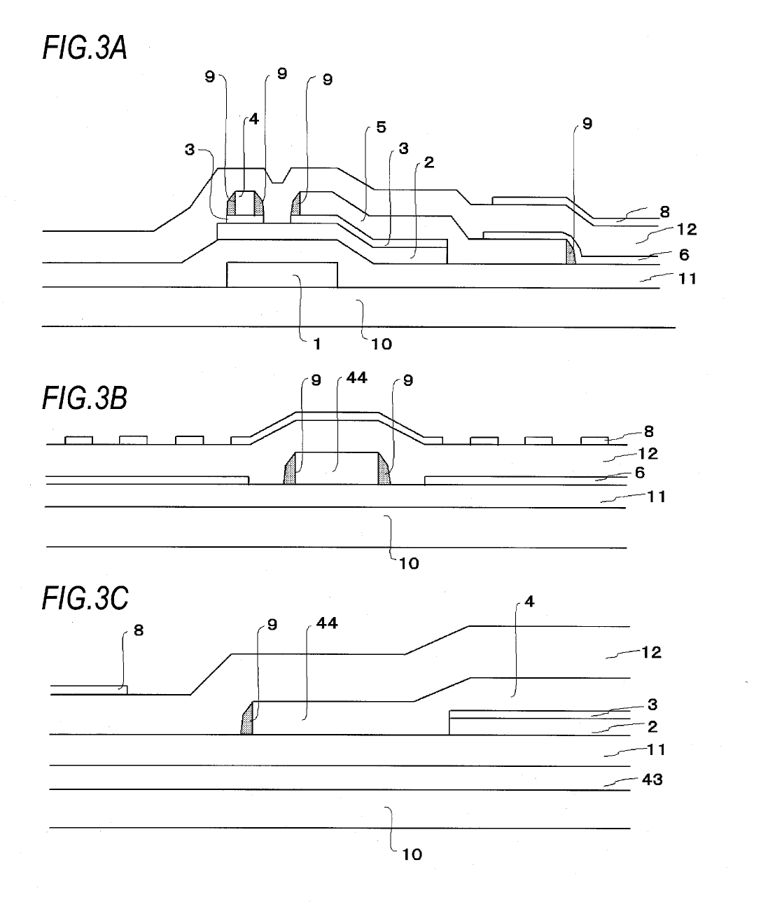

Subsequently, the pixel configuration of the liquid crystal display according to the present embodiment will be described with reference to FIG. 2 and FIGS. 3A to 3C. FIG. 2 is a plan view illustrating the pixel configuration of the TFT array substrate which is used in the liquid crystal display according to the present embodiment. FIGS. 3A to 3C are cross-sectional views illustrating the pixel configuration of the TFT array substrate which is used in the liquid crystal display according to the present embodiment. FIG. 2 shows one of the pixels 47 of the TFT array substrate. FIG. 3A is a cross-sectional view according to a line IIIA-IIIA of FIG. 2, and FIG. 3B is a cross-sectional view according to a line IIIB-IIIB of FIG. 2. Here, a case, where channel-etch type TFTs 50 are formed, will be described as an example.

In FIG. 2 and FIGS. 3A to 3C, the gate wirings 43 are formed on the transparent insulating substrate 10 made of glass, and a part of the gate wirings 43 configures a gate electrode 1. The gate wirings 43 are provided to linearly extend in one direction on the substrate 10. For example, the gate electrodes 1 and the gate wirings 43 are formed of Cr, Al, Ta, Ti, Mo, W, Ni, Cu, Au, or Ag, an alloy film composed mainly of them, or a laminated film of them.

To cover the gate electrodes 1 and the gate wirings 43, a gate insulating film 11 are provided as a first insulating film. The gate insulating film 11 is formed of an insulating film of silicon nitride, silicon oxide, or the like. Further, in the formation areas of the TFTs 50, semiconductor layers 2 are provided to face the gate electrodes 1 with the gate insulating film 11 interposed therebetween. Here, the semiconductor layers 2 are formed on the gate insulating film 11 to overlap the gate wirings 43, and areas of the gate wiring 43 overlapping the semiconductor layer 2 become the gate electrodes 1. For example, the semiconductor layers 2 are made of amorphous silicon, polycrystalline silicon, or the like.

Also, at both ends of each semiconductor layer 2, ohmic-contact films 3 doped with conductive impurities are formed, respectively. Areas of the semiconductor layer 2 corresponding to the ohmic-contact films 3 become source/drain areas. Specifically, in FIG. 3A, an area of a semiconductor layer 2 corresponding to the left ohmic-contact film 3 becomes a source area. Further, in FIG. 3A, an area of the semiconductor layer 2 corresponding to the right ohmic-contact film 3 becomes a drain area. Like this, the source and drain areas are formed at both ends of the semiconductor layer 2. Further, an area of the semiconductor layer 2 interposed between the source and drain areas becomes a channel area. Any ohmic-contact film 3 is not formed on the channel area of the semiconductor layer 2. For example, the ohmic-contact films 3 are formed of n-type amorphous silicon, n-type polycrystalline silicon, or the like heavily doped with impurities such as phosphorus (P).

A source electrode 4 and a drain electrode 5 are formed, on the ohmic-contact films 3. Specifically, on the ohmic-contact film 3 of the source area side, the source electrode 4 is formed and side walls 9 are formed of third insulating films on the side portions of the source electrode 4. Further, on the ohmic-contact film 3 on the drain area side, the drain electrode 5 is formed and side walls 9 are formed of a third insulating film on the side portions of the drain electrode 5. Like this, a channel-etch type TFT 50 is configured. Further, the source electrode 4, the side walls 9 on the side portions of the source electrode, the drain electrode 5, and the side walls 9 on the side portions of the drain electrode are formed to extend toward the outer sides of the channel area of the semiconductor layer 2. In other words, similarly to the ohmic-contact films 3, the source electrode 4, the drain electrode 5, and the side walls 9 are not formed on the channel area of the semiconductor layer 2.

The source electrode 4 and the side walls 9 on the side portions of the source electrode extend toward an outer side of the channel area of the semiconductor layer 2 and are connected to the source wiring 44. Side walls 9 are formed the side portions of the source wiring 44. The source wiring 44 and the side walls 9 are formed on the gate insulating film 11, and are disposed to linearly extend in a direction intersecting with the gate wiring 43 on the substrate 10.

Therefore, the source electrode 4 and the side walls 9 on the side portions of the source electrode branch at the intersection with the gate wiring 43 and extend along the gate wiring 43, and then the side walls 9 are formed of the insulating film on the side portions of the source electrode 4.

The drain electrode 5 and the side walls 9 formed on the side portions of the drain electrode extend toward an outer side of the channel area of the semiconductor layer 2. The pixel electrode 6 is electrically connected to the upper portion of the drain electrode 5 beyond a side wall 9 on a side wall of the drain electrode. In other words, the drain electrode 5 and the side walls 9 on the side portions of the drain electrode have portions extending to a pixel 47 on the outer side of the TFT 50. In other words, the drain electrode 5 and the pixel electrode 6 are electrically connected at the extending portions.

For example, the source electrode 4, the drain electrode 5, and the source wiring 44 are formed of Cr, Al, Ta, Ti, Mo, W, Ni, Cu, Au, or Ag, an alloy film composed mainly of them, or a laminated film of them. The side walls 9 on the side portions of the source wiring 44, the side walls 9 on the side portions of the source electrode 4, and the side walls 9 on the side portions of the drain electrode 5 are formed of a single film or laminated film of inorganic insulating films such as silicon nitride, silicon oxide, and the like.

Here, in the present embodiment, the pixel electrode 6 is formed such that a portion of the pixel electrode 6 overlaps on a top of the drain electrode 5 via a top of the side wall 9 formed on the side portion of the end surface of the extending portion of the drain electrode 5, and the pixel electrode 6 is electrically connected to the drain electrode 5. The pixel electrode 6 is formed to extend from the extending portion of the drain electrode 5 into the pixel 47 beyond the side wall 9.

Specifically, as shown in FIG. 2 and FIGS. 3A and 3C, the pixel electrode 6 is provided apart from the source wiring 44, the side walls 9 formed on the side portions of the source wiring 44, and the gate wiring 43, so as not to overlap them, and the pixel electrode 6 is formed on almost entire surface of an area surrounded by the source wiring 44, the side walls 9 formed on the side portions of the source wiring 44, and the gate wiring 43, except for the TFT 50. The pixel electrode 6 is formed of a transparent insulating film such as ITO or the like.

Since the side portions of the source wiring 44 are covered with the side walls 9, even if the pixel electrode is formed in the pixel 47 surrounded by the source wiring 44 without forming an inter-layer insulating film, the side portions of the source wiring 44 are insulated from the pixel electrode 6 by the side walls 9. In other words, even if an anomaly occurs in the shape of the pixel electrode 6 in the pixel 47, or residues or the like are generated during a process, the pixel electrode 6 of the present embodiment is insulated from the source wiring 44 by the side walls 9 on the side portions of the source wiring. Even if the pixel electrode 6 and the source wiring 44 are at the same layer without any inter-layer insulating film, the pixel electrode 6 and the source wiring 44 are not electrically short-circuited. Also, even if the pixel electrode 6 is extended up to the vicinity of the source wiring and an opening area of the pixel is extended, since the side portions of the source wiring 44 are protected by the insulating films, it is unnecessary to keep a distance between the pixel electrode 6 and the source wiring 44 in view of the yield, and then it becomes possible to dispose the pixel electrode 6 in view of only an electric field with the source wiring, and thus it becomes possible to improve the aperture ratio of the pixel.

Also, the drain electrode 5 formed to extend from the TFT 50 to the pixel 47, and the side portion of an end portion of the drain electrode 5 inside the pixel 47, is provided with the side wall 9. Therefore, in a case of making the pixel electrode 6 overlap the drain electrode 5, even if the tapered shape of the end portion of the drain electrode 5 is thinned or the thickness of the pixel electrode 6 is thinned for improving the transmittance, a drain electrode structure having the improved covering property of the pixel electrode 6 and suppressing the pixel electrode 6 from being disconnected is possible.

Further, in a case where the source electrode 4 and the drain electrode 5 are formed of an alloy film of materials such as Al, Ta, Ti, Mo, W, Ni, and Cu, or a laminated film of them and there are no side walls on the end portions of the source electrode 4 and the drain electrode 5 between channels, when channel-etch is performed, conductive residues are formed between the channels by reaction of the electrode material and an etchant (such as fluorine), and cause off-leak between the source electrode 4 and the drain electrode 5 formed between the channels. As a result, the properties of the TFT gets worse and the display properties of the liquid crystal are deteriorated. Since the side walls 9 are formed on the side portions of the source electrode 4 and the drain electrode 5 of both ends of the channel area, diffusion of the residues to a portion between the channels by a conductive product generated from the source electrode 4 and the drain electrode 5 due to etching during channel formation can be ensured by the side walls 9.

In order to cover the source electrode 4, the drain electrode 5, the source wiring 44, the side walls 9 formed on the side portions of them, and the pixel electrode 6, an inter-layer insulating film 12 is provided as a second insulating film. The inter-layer insulating film 12 is formed of an insulating film of silicon nitride, silicon oxide, or the like. Further, in the present embodiment, on the inter-layer insulating film 12, a counter electrode 8 is formed. The counter electrode 8 is provided to face the pixel electrode 6 with the inter-layer insulating film 12 and has slits for generating a fringe electric field between the counter electrode 8 and the pixel electrode 6. The silts are provided in almost parallel to the source wiring 44 as shown in FIG. 2. For example, the slits are provided linearly in a direction intersecting with the gate wiring 43. The counter electrode 8 is formed of a transparent conductive film of ITO or the like.

Also, the counter electrode 8 is formed to cover the source wirings 44. Specifically, as shown in FIGS. 2 and 3B, the counter electrode 8 wider than the source wirings 44 is provided to face the source wirings 44 with the inter-layer insulating film 12 interposed therebetween. The counter electrode 8 covers most of each source wiring 44 of the pixel portion. In other words, most of an area of each source wiring 44 except for portions intersecting with the gate wirings 43 overlaps the counter electrode 8. According to this configuration, since an electric field generated from the source wirings 44 is shielded by the counter electrode 8 so as not to reach the liquid crystal, it is possible to reduce a change in the oriented state of the liquid crystal. Therefore, since light leakage due to an electric field generated by the source wirings 44 is remarkably suppressed, on the counter substrate side, it is unnecessary to form a black matrix in a wide range to cover the source wirings 44. As a result, it is possible to reduce a non-transparent area of the vicinity of each source wiring 44, and thus the aperture ratio is improved.

Hereinafter, a method of manufacturing the liquid crystal display according to the present embodiment will be described. First, onto the entire surface of the transparent insulating substrate 10 of glass or the like, a film is formed of Cr, Al, Ta, Ti, Mo, W, Ni, Cu, Au, or Ag, an alloy film composed mainly of them, or a laminated film of them. For example, a sputtering method, a vapor deposition method, or the like is used to form a film on the entire surface of the substrate 10. Then, a resist is applied, and the applied resist is exposed to light from above a photomask. Next, the exposed resist is developed, whereby the resist is patterned. Hereinafter, this series of processes will be referred to as a photoengraving process. Next, etching is performed using the resist pattern as a mask, and the photoresist pattern is removed. Hereinafter, this process will be referred to as a fine processing technology. In this way, the gate electrodes 1 and the gate wirings 43 are formed by patterning.

Next, the first insulating film to be the gate insulating film 11, a film to be the semiconductor layers 2, and a film to be the ohmic-contact films 3 are sequentially formed to cover the gate electrodes 1 and the gate wirings 43. For example, plasma CVD, atmospheric pressure CVD, low pressure CVD, or the like is used to form those films on the entire surface of the substrate 10. The gate insulating film 11 can be made of silicon nitride, silicon oxide, or the like. Also, in order to suppress short-circuiting due to occurrence of a film defect such as a pinhole, it is preferable to form the gate insulating film 11 over a plurality of times.

The semiconductor layers 2 can be made of amorphous silicon, polycrystalline silicon, or the like. Also, the ohmic-contact films 3 can be made of n-type amorphous silicon, n-type polycrystalline silicon, or the like containing impurities such as phosphorus (P) at a high concentration. Then, the photoengraving process and the fine processing technology are used to pattern the film to be the semiconductor layers 2 and the film to be the ohmic-contact films 3 into island shapes on the gate electrodes 1.

Next, in the present embodiment, so as to cover them, a film is formed of Cr, Al, Ta, Ti, Mo, W, Ni, Cu, Au, or Ag, an alloy film composed mainly of them, or a laminated film of them. For example, a sputtering method, a vapor deposition method, or the like is used to form the film. Then, patterning is performed by the photoengraving process and the fine processing technology, so that the source electrodes 4, the drain electrodes 5, and the source wirings 44 are formed.

Next, so as to cover the source electrodes 4, the drain electrodes 5, and the source wirings 44, the third insulating film to be the side walls 9 is formed, for example, using plasma CVD, atmospheric pressure CVD, low pressure CVD, or the like. The side walls 9 can be made of a single film or laminated film of inorganic insulating films of silicon nitride, silicon oxide, and the like. Then, without performing the photoengraving process, highly anisotropic dry etching using a composition such as CF₄, CHF₃, or Ar gas is performed on the silicon nitride and/or silicon oxide film, such that the side walls 9 are formed of the insulating film for remedying short-circuiting or disconnection of the pixel electrodes 6 and leak between channels, on the side portions of the source electrodes 4, the drain electrodes 5, and the source wirings 44.

Subsequently, so as to cover the source electrodes 4, the drain electrodes 5, the source wirings 44, and the side walls 9, a transparent conductive film is formed of ITO or the like on the entire surface of the substrate 10 by a sputtering method or the like. Then, patterning is performed on the transparent conductive film by the photoengraving process and the fine processing technology. As a result, a portion of the pixel electrodes 6 are formed to directly overlap on the drain electrodes 5.

As described above, since the side portions of the source wirings 44 are insulated and protected by the side walls 9, the pixel electrodes 6 formed inside the pixels 47 are suppressed from coming into contact with the source wirings 44, resulting in lighting failure of the pixels. Also, since the side portions of the end portions of the drain electrodes 5 inside the pixels 47 improve the tapered shapes of the electrodes, even if the thicknesses of the pixel electrodes 6 are thinned for increasing the transmittance, disconnection and the like hardly occur.

Next, etching is performed on the film to be the ohmic-contact films 3, using the source electrodes 4, the drain electrodes 5, and the side walls 9 on the side portions of those electrodes, as a mask. In other words, of the ohmic-contact films 3 formed in island shapes by patterning, portions exposed without being covered with the source electrodes 4, the drain electrodes 5, or the side walls 9 on the side portions of those electrodes are removed by etching. As a result, the ohmic-contact films 3 and the semiconductor layers 2 having channel areas between the source electrodes 4 and the drain electrodes 5 are formed. Also, in the above description, after the pixel electrodes 6 are formed, etching on the ohmic-contact films is performed. However, etching of the ohmic-contact films may be performed sequentially to the formation of the side walls 9.

Since the side walls 9 are formed on the side portions of the source electrodes 4 and the drain electrodes 5 and then the etching on the ohmic-contact films is performed, during the etching on the ohmic-contact films, conductive residues are not generated from the source electrodes 4 and the drain electrodes 5 by etching on the channels. Therefore, it becomes possible to form transistors whose off-leak properties is not deteriorated. The process of forming the side walls 9 makes it possible to form thin film transistors suppressing a deterioration of the display properties and a reduction of the yield due to electrical short-circuiting and disconnection, at once.

Subsequently, so as to cover the source electrodes 4, the drain electrodes 5, the source wirings 44, the side walls 9, and the pixel electrodes 6, the second insulating film to be the inter-layer insulating film 12 is formed. For example, as the inter-layer insulating film 12, an inorganic insulating film is formed of silicon nitride, silicon oxide, or the like on the entire surface of the substrate 10 by a CVD method or the like. As a result, the channel areas of the semiconductor layers 2 are covered with the inter-layer insulating film 12. Incidentally, in the frame area 42, terminals (not shown) for connection with the scan signal driver circuit 45 or the display signal driver circuit 46 are formed by the same layers as those for the gate wirings 43 or the source wirings 44. Therefore, after the inter-layer insulating film 12 is formed, contact holes are formed in the inter-layer insulating film 12 and the gate insulating film 11 by the photoengraving process and the fine processing technology such that the contact holes reach those terminals.

Next, on the inter-layer insulating film 12, a transparent conductive film is formed of ITO or the like over the entire surface of the substrate 10 by a sputtering method or the like. Then, patterning is performed on the transparent conductive film by the photoengraving process and the fine processing technology. As a result, the counter electrode 8 having the slits is formed to face the pixel electrodes with the inter-layer insulating film 12 interposed therebetween. Further, the counter electrode 8 is formed to cover most of each source wiring 44 and at least a portion of each gate wiring 43 and to be connected to counter electrodes 8 of neighboring pixels. Furthermore, in the frame area 42, gate terminal pads are formed by the same transparent conductive film as that for the counter electrode 8 such that the gate terminal pads are connected to gate terminals through the contact holes. Similarly, source terminal pads are formed by the same transparent conductive film as that for the counter electrode 8 such that the source terminal pads are connected to source terminals through the contact holes. Through the above-mentioned processes, the TFT array substrate of the present embodiment is completed.

An alignment film is formed on the TFT array substrate manufactured as described above by the subsequent cell process. Also, an alignment film is similarly formed on the counter substrate separately manufactured. Then, with respect to the alignment films, an aligning process (rubbing process) of leaving micro scratches in one direction on their contact surfaces with the liquid crystal is performed. Next, a seal material is applied, and then the TFT array substrate and the counter substrate are bonded. After the TFT array substrate and the counter substrate are bonded, the liquid crystal is injected from a liquid crystal inlet by a vacuum injection method or the like. Then, the liquid crystal inlet is sealed. On both surfaces of the liquid crystal cell formed as described above, polarizing plates are bonded, drive circuits are connected, and then the backlight unit is attached. In this way, the liquid crystal display of the present embodiment is completed.

### Second Embodiment

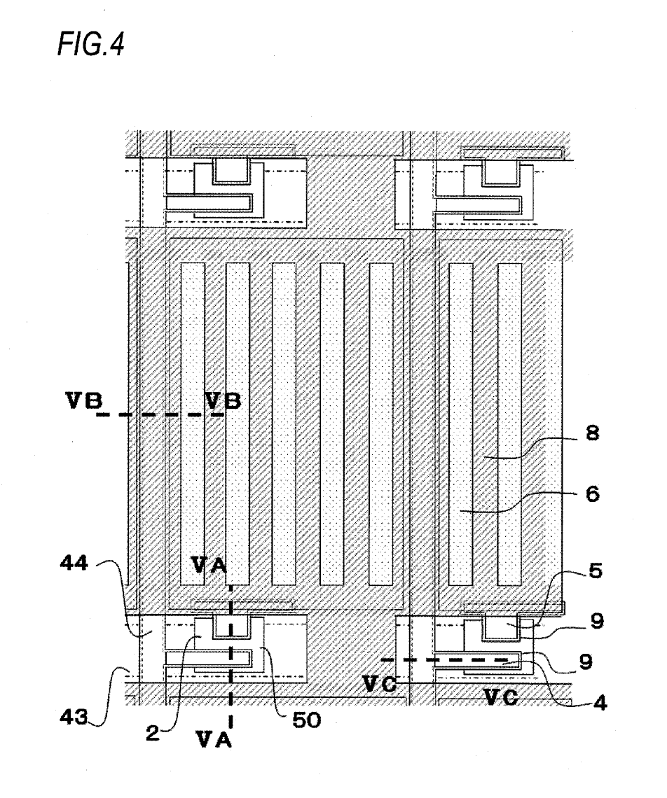

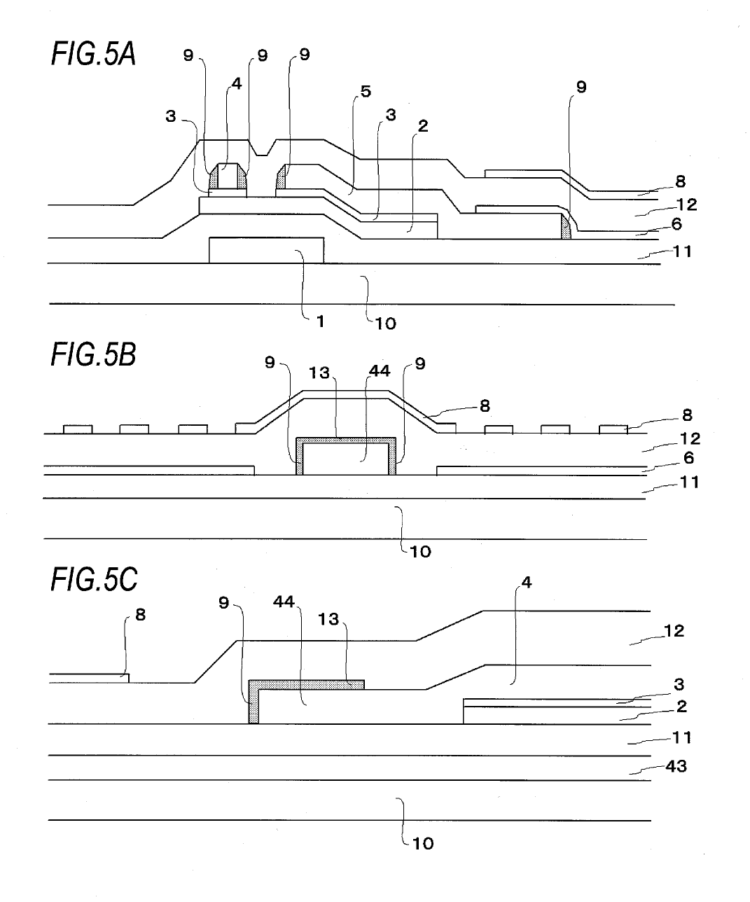

The pixel configuration of a liquid crystal display of the present embodiment will be described with reference to FIG. 4 and FIGS. 5A to 5C. FIG. 4 is a plan view illustrating one pixel of a TFT array substrate which is used in the liquid crystal display according to the second embodiment. FIGS. 5A to 5C are cross-sectional views illustrating the pixel configuration of the TFT array substrate which is used in the liquid crystal display according to the second embodiment. FIG. 5A is a cross-sectional view along a line VA-VA of FIG. 4, FIG. 5B is a cross-sectional view along a line VB-VB of FIG. 4, and FIG. 5C is a cross-sectional view along a line VC-VC of FIG. 4.

FIG. 5A shows the structure of an area where a source electrode 4 and a drain electrode 5 face the semiconductor layer 3. However, this area has the same structure as that of the first embodiment, and thus it will not be described in detail. Meanwhile, as described in FIG. 5B which is a cross-sectional view illustrating a source wiring 44 and FIG. 5C which is a cross-sectional view illustrating an area where the source wiring 44 and a source electrode 4 are integrally connected, structures different from those of the first embodiment are shown.

First, in FIG. 5B, similarly to the first embodiment, side walls 9 are formed on the side portions of the source wiring 44. Meanwhile, unlike the first embodiment, a source wiring insulating film 13 is formed on the source wiring 44. In other words, an insulating film provided between the source wiring 44 and a counter electrode 8 is provided to include not only the inter-layer insulating film 12 but also the source wiring insulating film 13.

Next, as shown in FIG. 5C, even in the area where the source electrode 4 and the source wiring 44 are connected, the side walls 9 are formed on the side portions of the source wiring 44, and the source wiring insulating film 13 is formed on the source wiring 44. Here, it should be noted that the insulating film is formed on the source wiring 44 and but any insulating film is not formed on the source electrode 4.

The second embodiment is characterized in that the insulating film which is formed as the side walls 9 on the side portions of the source wiring 44 is provided as the source wiring insulating film 13 even on the top of the source wiring 44. The other configuration is the same as that of the first embodiment, and it thus will not be described.

In other words, in the structure of the second embodiment, the third insulating film to form the side wall 9 is provided between the source wiring 44 and the inter-layer insulating film 12. In other words, the source wiring 44 is covered by the source wiring insulating film 13 which is the insulating film forming the side walls 9, and the source wiring insulating film 13 extends along the source wiring 44 between neighboring pixel electrodes 6. Also, the side walls 9 and the source wiring insulating film 13 can be made of a single film or laminated film of inorganic insulating films of silicon nitride, silicon oxide, and the like.

A method of manufacturing a TFT array substrate having the above configuration will be described. Processes up to a process of forming the third insulating film to be the side walls 9 are the same as those of the first embodiment, and thus it will not be described. In the first embodiment, after the process of forming the third insulating film, highly anisotropic dry etching is performed without performing the photoengraving process; whereas in the second embodiment, the photoengraving process is performed such that a resist covers at least the each source wiring 44. After the photoengraving process is performed, similarly to the first embodiment, highly anisotropic dry etching using CF₄, CHF₃, Ar gas, or the like is performed on the silicon nitride and/or silicon oxide film, and then the resist is removed. As a result, similarly to the first embodiment, the side walls 9 are formed on the side portions of the source wiring 44, and the source wiring insulating film 13 is formed above the source wiring 44. Meanwhile, in a case of the source electrode 4 and the drain electrode 5, the side walls 9 are formed only on their side walls. Here, the process of etching on the ohmic-contact layer may be performed sequentially to the formation of the side walls 9.

Sequentially, so as to cover the source electrode 4, the drain electrode 5, the source wiring 44, the side walls 9, and the source wiring insulating film 13, a transparent conductive film is formed of ITO or the like over the entire surface of the substrate 10 by a sputtering method. The subsequent processes are the same as those of the first embodiment, and thus it will not be described. Also, according to the above-mentioned manufacturing method, the source wiring insulating film 13 is composed of the same third insulating film as that for the side walls 9. However, the source wiring insulating film 13 may be formed of a material different from that of the side walls 9 and have a thickness different from those of the side walls 9.

As described above, in the second embodiment, the insulating film is formed to cover not only on the side portions of the source wiring 44 but also on the top of the source wiring 44. In other words, an insulating film which is provided between the source wiring 44 and the counter electrode 8 is composed of the insulating film of the side walls 9 and the inter-layer insulating film 12, and thus the inter-layer thickness becomes thick. Therefore, a capacitive component between the counter electrode 8 and the source wiring 44 is further reduced, and thus it is possible to further reduce a change in the oriented state of the liquid crystal.

Also, in addition to the methods of this disclosure, for example, a method of forming one more insulating film below the inter-layer insulating film 12 can be considered. However, this method reduces the capacitance between a pixel electrode and a counter electrode. In the second embodiment, it is possible to reduce the capacitance between the source wirings and the common electrode without causing that problem.

What is claimed is:

1. A liquid crystal display which includes a first substrate having thin film transistors, a second substrate disposed to face the first substrate, and liquid crystal interposed between the first substrate and the second substrate,
wherein the first substrate includes:
a gate electrode, a source electrode, and a drain electrode that configure the thin film transistor;
a gate wiring that is connected to the gate electrode;
a first insulating film that is formed on the gate electrode and the gate wiring;
a source wiring that is formed to be perpendicular to the gate wiring, and are connected to the source electrode;
a pixel electrode that is formed on the drain electrode formed on the first insulating film such that the pixel electrode partially overlap the drain electrode;
a second insulating film that covers the pixel electrode;
a counter electrode that is formed on the second insulating film and has slits to generate a fringe electric field between the counter electrode and the pixel electrode; and
a side wall that is formed on side portions of the source wiring, the source electrode, and the drain electrode, the third insulating film made of third insulating film; and
wherein at least a part of the pixel electrode is formed to directly overlap the drain electrode and the side wall formed on the side portion of the drain electrode.

2. The liquid crystal display according to claim 1,
wherein the third insulating film is formed on the source wiring.

3. A method of manufacturing a liquid crystal display, comprising:
forming a gate electrode and a gate wiring which are connected to the gate electrode on a first substrate;
forming a first insulating film to cover the gate electrode and the gate wiring;
forming a source wiring, a source electrode connected to the source wiring, and a drain electrode on the first insulating film such that the source wiring intersect with the gate wiring;
forming a pixel electrode to partially overlap the drain electrode;
forming a second insulating film to cover the pixel electrode; and
forming a counter electrode with slits to generate a fringe electric field between the counter electrode and the pixel electrode, on the second insulating film;
the method further comprising:
forming a side wall on side portions of the source wiring, the source electrode, and the drain electrode, the side wall made of a third insulating film;
wherein, in the forming the pixel electrode, at least a part of the pixel electrode is formed to directly overlap the drain electrode and the side wall formed on the side portion of the drain electrode.
